(19) United States
(12) Patent Application Publication
(10) Pub. No.: US 2026/0215327 A1
(43) Pub. Date: Jul. 23, 2026

(54) SEMICONDUCTOR DEVICE

(71) Applicant: Mitsubishi Electric Corporation, Tokyo (JP)

(72) Inventor: Tomoyuki HIGO, Fukuoka (JP)

(73) Assignee: Mitsubishi Electric Corporation, Tokyo (JP)

(21) Appl. No.: 19/416,998

(22) Filed: Dec. 11, 2025

(30) Foreign Application Priority Data
Jan. 21, 2025 (JP) 2025-008372

(51) Int. Cl. H10W 74/10; H10D 62/10; H10W 74/47

(52) U.S. Cl. CPC H10W 74/121; H10D 62/107; H10W 74/47

(57) ABSTRACT

A semiconductor device includes an energization region, a breakdown voltage retention region, and an invalid region. The breakdown voltage retention region is provided to surround the energization region, and the invalid region is provided to surround the breakdown voltage retention region. The breakdown voltage retention region and the invalid region include a protective film of a plurality of layers and an encapsulant. The protective film of the plurality of layers includes a first protective film made of a resin, and a second protective film provided on the first protective film. The encapsulant is provided on the protective film of the plurality of layers. The first protective film is larger in thermal expansion coefficient than the semiconductor substrate. The second protective film is larger in thermal expansion coefficient than the first protective film, and smaller in thermal expansion coefficient than the encapsulant.

### BACKGROUND

### Technical Field

The present disclosure relates to a semiconductor device.

### Description of the Background Art

Semiconductor devices for power control each include a breakdown voltage retention region in a semiconductor substrate. In the breakdown voltage retention region, a protective film covering the semiconductor substrate and an encapsulant on the upper surface of the protective film are formed (see, for example, Japanese Patent Application Laid-Open No. 2021-132171).

When the number of layers in the protective film provided in the breakdown voltage retention region and a termination region is only one, a test of repeating a high-temperature state and a low-temperature state such as a temperature cycle test and a test to which a humidity change has been added often result in peeling or a crack of the encapsulant on the protective film. These are caused by a thermal stress occurring depending on a difference in thermal expansion coefficient between the protective film and the encapsulant. The peeling and the crack of the encapsulant induce a breakdown voltage failure and a poor appearance of a semiconductor device, and decrease the reliability of the semiconductor device.

### SUMMARY

The present disclosure has an object of providing a semiconductor device in which failures of an encapsulant will decrease.

A semiconductor device according to the present disclosure includes an energization region, a breakdown voltage retention region, and an invalid region. The energization region corresponds to a region in which a main current controlled by a semiconductor element flows, the semiconductor element being formed in a semiconductor substrate. The breakdown voltage retention region is provided to surround the energization region, and the invalid region is provided to surround the breakdown voltage retention region. The breakdown voltage retention region and the invalid region include a protective film of a plurality of layers and an encapsulant. The protective film of the plurality of layers including a first protective film provided on an upper surface side of the semiconductor substrate and made of a resin, and a second protective film provided on the first protective film, the first protective film. The encapsulant is provided on the protective film of the plurality of layers. The first protective film is larger in thermal expansion coefficient than the semiconductor substrate. The second protective film is larger in thermal expansion coefficient than the first protective film, and smaller in thermal expansion coefficient than the encapsulant.

A semiconductor device in which failures of an encapsulant will decrease will be provided.

These and other objects, features, aspects, and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a structure of a semiconductor device according to Embodiment 1;

FIG. 2 is a cross-sectional view illustrating the structure of the semiconductor device;

FIG. 3 is a plan view illustrating a structure of a semiconductor device according to Embodiment 2;

FIG. 4 is a cross-sectional view illustrating a structure of a semiconductor device according to Embodiment 3; and

FIGS. 5A to 5C are plan views each illustrating a structure of a second protective film in the semiconductor device.

### DESCRIPTION OF THE PREFERRED EMBODIMENTS

### Embodiment 1

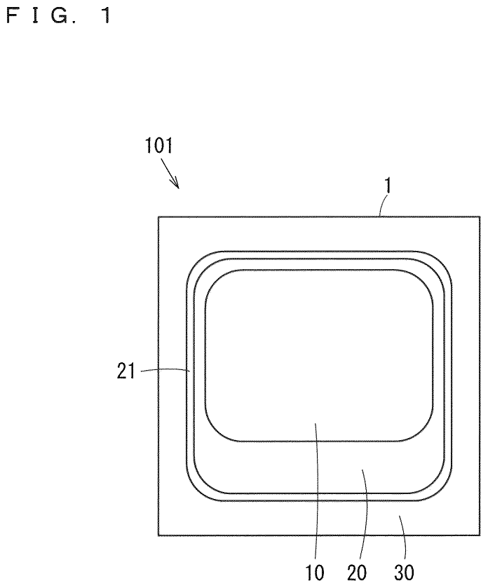

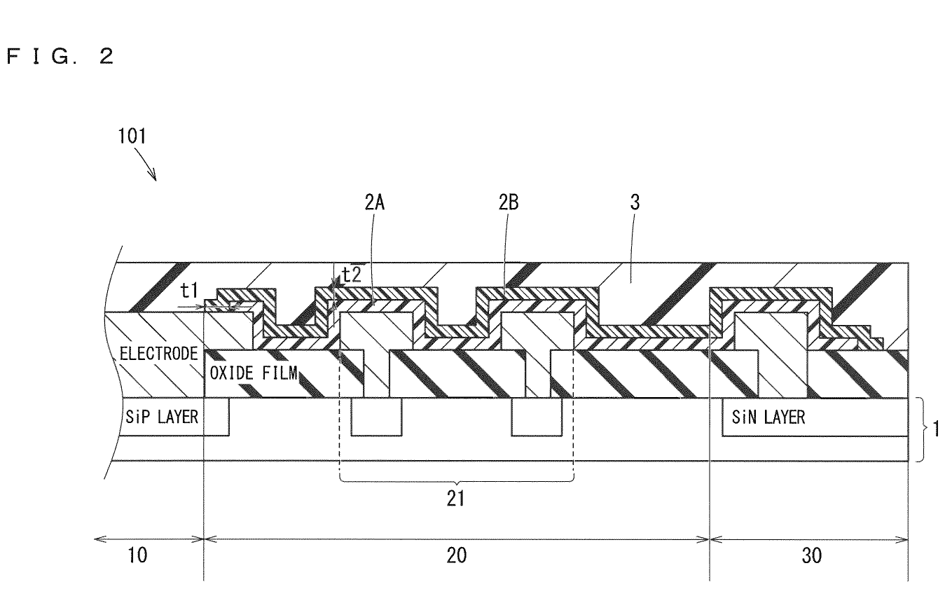

FIG. 1 is a plan view illustrating a structure of a semiconductor device 101 according to Embodiment 1. FIG. 2 is a cross-sectional view illustrating the structure of the semiconductor device 101. The semiconductor device 101 includes an energization region 10, a breakdown voltage retention region 20, and an invalid region 30 which are provided in a semiconductor substrate 1.

The energization region 10 includes a semiconductor element (not illustrated) formed in the semiconductor substrate 1, and corresponds to a region in which a main current controlled by the semiconductor element flows. The semiconductor element is made of a semiconductor material such as Si. The semiconductor element may be made of, for example, a wide bandgap semiconductor such as SiC or GaN in semiconductor materials. Examples of the semiconductor element include an insulated-gate bipolar transistor (IGBT), a metal-oxide semiconductor field-effect transistor (MOSFET), and a Schottky barrier diode. Alternatively, the semiconductor element may be a reverse-conducting IGBT (RC-IGBT) in which an IGBT and a freewheeling diode are formed in the single semiconductor substrate 1.

The breakdown voltage retention region 20 is provided to surround the energization region 10 in a plan view. The invalid region 30 is provided to surround the breakdown voltage retention region 20 in a plan view. A field limiting ring (FLR) portion 21 is formed in the breakdown voltage retention region 20 in the semiconductor substrate 1 according to Embodiment 1 as a breakdown voltage retention structure. The FLR is also referred to as a guard ring. The breakdown voltage retention structure is not limited to the FLR portion 21 but may be another structure.

In the breakdown voltage retention region 20 and the invalid region 30, a protective film of a plurality of layers and an encapsulant 3 are provided on an upper surface side of the semiconductor substrate 1. The protective film of the plurality of layers includes a first protective film 2A made of a resin such as polyimide, and a second protective film 2B provided on the first protective film 2A. The protective film according to Embodiment 1 has a two-layer structure. The encapsulant 3 according to Embodiment 1 is provided on the protective film of the plurality of layers, and is in contact with the upper surface of the second protective film 2B.

It is preferred that the second protective film 2B is provided to cover not only the upper surface of the first protective film 2A but also the side surface at the edges of the first protective film 2A. It is also preferred that t1≥t2 holds as a relationship between a distance t1 from an edge of the first protective film 2A and an edge of the second protective film 2B and a thickness t2 of the second protective film 2B.

The first protective film 2A is larger in thermal expansion coefficient than the semiconductor substrate 1. The second protective film 2B is larger in thermal expansion coefficient than the first protective film 2A, and smaller in thermal expansion coefficient than the encapsulant 3.

As such, the protective film of the plurality of layers is provided in the semiconductor device 101, and gradients are provided in the thermal expansion coefficients from the semiconductor substrate 1 to the encapsulant 3. When a temperature change occurs by driving the semiconductor device 101, a thermal stress occurring between the semiconductor substrate 1 and the encapsulant 3 is relaxed by the first protective film 2A and the second protective film 2B. This results in a decrease in the peeling and a crack of the encapsulant 3.

In summary, the semiconductor device 101 according to Embodiment 1 includes the energization region 10, the breakdown voltage retention region 20, and the invalid region 30. The energization region 10 corresponds to a region in which a main current controlled by a semiconductor element flows, the semiconductor element being formed in the semiconductor substrate 1. The breakdown voltage retention region 20 is provided to surround the energization region 10, and the invalid region 30 is provided to surround the breakdown voltage retention region 20. The breakdown voltage retention region 20 and the invalid region 30 include a protective film of a plurality of layers and the encapsulant 3. The protective film of the plurality of layers includes the first protective film 2A provided on an upper surface side of the semiconductor substrate 1 and made of a resin, and the second protective film 2B provided on the first protective film 2A. The encapsulant 3 is provided on the protective film of the plurality of layers. The first protective film 2A is larger in thermal expansion coefficient than the semiconductor substrate 1. The second protective film 2B is larger in thermal expansion coefficient than the first protective film 2A, and smaller in thermal expansion coefficient than the encapsulant 3.

In the semiconductor device 101, failures of the encapsulant 3 such as the peeling and the crack of the encapsulant 3 will decrease. Consequently, the reliability of the semiconductor device 101 will be enhanced.

It is preferred that a difference in thermal expansion coefficient between the first protective film 2A and the second protective film 2B is 5.0×10⁻⁶/K or less. It is also preferred that a difference in thermal expansion coefficient between the second protective film 2B and the encapsulant 3 is 5.0×10⁻⁶/K or less.

The protective film of the plurality of layers may be a protective film of three or more layers of which illustration is omitted. For example, the semiconductor device 101 may further include a third protective film provided on the second protective film 2B. In such a case, the second protective film 2B is larger in thermal expansion coefficient than the first protective film 2A, and smaller in thermal expansion coefficient than the third protective film. The third protective film is larger in thermal expansion coefficient than the second protective film 2B, and smaller in thermal expansion coefficient than the encapsulant 3. Such a structure produces the aforementioned advantages.

### Embodiment 2

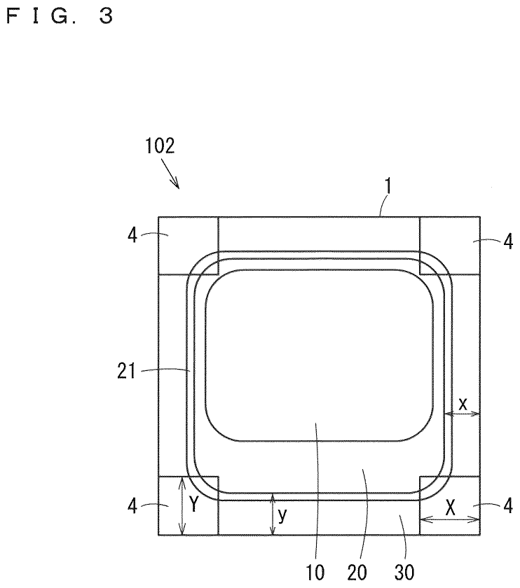

FIG. 3 is a plan view illustrating a structure of a semiconductor device 102 according to Embodiment 2. The semiconductor substrate 1 has a planar shape of a rectangle. The protective film of the plurality of layers is provided in corner portions 4 included in the rectangle of the semiconductor substrate 1 in the breakdown voltage retention region 20 and the invalid region 30. Regions in which the second protective film 2B is laminated on the upper surface of the first protective film 2A are limited to the four corner portions 4. The second protective film 2B is not provided in the breakdown voltage retention region 20 and the invalid region 30 except the four corner portions 4, and the encapsulant 3 is directly laminated on the first protective film 2A. A width (X or Y in FIG. 3) of each of the corner portions 4 corresponds to a width of the region in which the second protective film 2B is laminated on the upper surface of the first protective film 2A.

The FLR portion 21 is provided in the breakdown voltage retention region 20, similarly to Embodiment 1.

The width (X or Y in FIG. 3) of each of the corner portions 4 in the semiconductor device 102 according to Embodiment 2 is larger than a distance (x or y in FIG. 3) from an edge of the semiconductor substrate 1 to an innermost circumference of the FLR portion 21 (X>x or Y>y).

When a temperature change occurs in the semiconductor device 102, regions in which a thermal stress given from the encapsulant 3 is the largest are the corner portions 4. The regions in which gradients are provided in the thermal expansion coefficients of the first protective film 2A, the second protective film 2B, and the encapsulant 3 are limited to the corner portions 4. When a temperature change occurs, the thermal stress occurring in the semiconductor substrate 1 and given from the encapsulant 3 is relaxed. This results in a decrease in the peeling and the crack of the encapsulant 3, and enhances the reliability of the semiconductor device 102.

### Embodiment 3

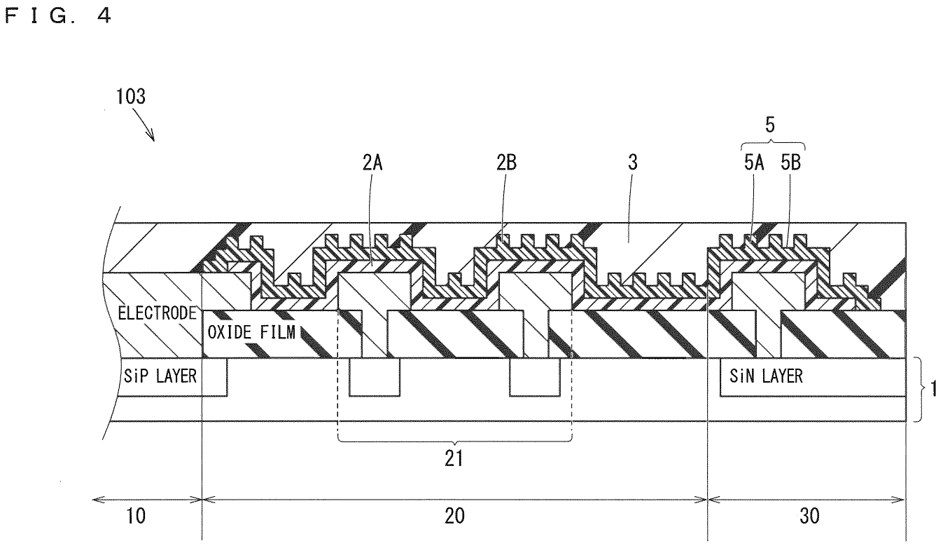

FIG. 4 is a cross-sectional view illustrating a structure of a semiconductor device 103 according to Embodiment 3. The semiconductor device 103 includes the energization region 10, the breakdown voltage retention region 20 provided to surround the energization region 10, and the invalid region 30 provided to surround the breakdown voltage retention region 20. The semiconductor device 103 has a planar shape of a rectangle.

As illustrated in FIG. 4, the upper surface of the second protective film 2B which in contact with the encapsulant 3 includes a roughness pattern 5 in Embodiment 3. It is preferred that the film thickness of the second protective film 2B in a protrusion 5A is 8.0 μm or more, and the film thickness of the second protective film 2B in a recess 5B is 4.0 μm or more.

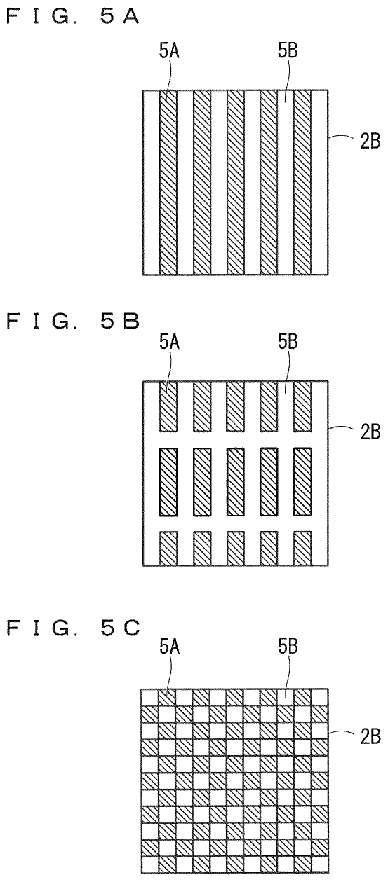

FIGS. 5A to 5C are plan views each illustrating a structure of the second protective film 2B in the semiconductor device 103. As illustrated in FIG. 5A, each of the protrusions 5A and the recesses 5B forming the roughness pattern 5 has, for example, a linear shape. As illustrated in FIG. 5B, the protrusions 5A may be dot-shaped. As illustrated in FIG. 5C, both of the protrusions 5A and the recesses 5B may be dot-shaped.

Forming the roughness pattern 5 in the second protective film 2B improves adhesion between the semiconductor substrate 1 and the encapsulant 3 with an anchor effect, in addition to the advantages of Embodiment 1. This results in decreases in the peeling of the encapsulant 3 and the crack in the semiconductor substrate 1.

Embodiments of the present disclosure can be freely combined, or appropriately modified and omitted.

A summary of various aspects of the present disclosure will be hereinafter described as Appendixes.

### Appendix 1

A semiconductor device, comprising:
an energization region corresponding to a region in which a main current controlled by a semiconductor element flows, the semiconductor element being formed in a semiconductor substrate;
a breakdown voltage retention region provided to surround the energization region; and
an invalid region provided to surround the breakdown voltage retention region,
the breakdown voltage retention region and the invalid region including:
a protective film of a plurality of layers including a first protective film provided on an upper surface side of the semiconductor substrate and made of a resin, and a second protective film provided on the first protective film; and
an encapsulant provided on the protective film of the plurality of layers,
wherein the first protective film is larger in thermal expansion coefficient than the semiconductor substrate, and
the second protective film is larger in thermal expansion coefficient than the first protective film, and smaller in thermal expansion coefficient than the encapsulant.

### Appendix 2

The semiconductor device according to appendix 1,
wherein the encapsulant is provided on the second protective film,
a difference in thermal expansion coefficient between the first protective film and the second protective film is 5.0×10−6/K or less, and
a difference in thermal expansion coefficient between the second protective film and the encapsulant is 5.0×10−6/K or less.

### Appendix 3

The semiconductor device according to appendix 1 or 2,
wherein the protective film of the plurality of layers is a protective film of three or more layers including a third protective film provided on the second protective film,
the second protective film is larger in thermal expansion coefficient than the first protective film, and smaller in thermal expansion coefficient than the third protective film, and
the third protective film is larger in thermal expansion coefficient than the second protective film, and smaller in thermal expansion coefficient than the encapsulant.

### Appendix 4

The semiconductor device according to any one of appendixes 1 to 3,
wherein the semiconductor substrate has a planar shape of a rectangle, and
the protective film of the plurality of layers is provided in corner portions included in the rectangle of the semiconductor substrate, in the breakdown voltage retention region and the invalid region.

### Appendix 5

The semiconductor device according to appendix 4,
wherein the breakdown voltage retention region includes a field limiting ring portion, and
a width of each of the corner portions is larger than a distance from an edge of the semiconductor substrate to an innermost circumference of the field limiting ring portion.

### Appendix 6

The semiconductor device according to any one of appendixes 1 to 5,
wherein the encapsulant is provided on the second protective film,
an upper surface of the second protective film includes a roughness pattern,
a film thickness of the second protective film in a protrusion of the roughness pattern is 8.0 μm or more, and
a film thickness of the second protective film in a recess of the roughness pattern is 4.0 μm or more.

What is claimed is:

1. A semiconductor device, comprising:
an energization region corresponding to a region in which a main current controlled by a semiconductor element flows, the semiconductor element being formed in a semiconductor substrate;
a breakdown voltage retention region provided to surround the energization region; and
an invalid region provided to surround the breakdown voltage retention region,
the breakdown voltage retention region and the invalid region including:
a protective film of a plurality of layers including a first protective film provided on an upper surface side of the semiconductor substrate and made of a resin, and a second protective film provided on the first protective film; and
an encapsulant provided on the protective film of the plurality of layers,
wherein the first protective film is larger in thermal expansion coefficient than the semiconductor substrate, and
the second protective film is larger in thermal expansion coefficient than the first protective film, and smaller in thermal expansion coefficient than the encapsulant.

2. The semiconductor device according to claim 1,
wherein the encapsulant is provided on the second protective film,
a difference in thermal expansion coefficient between the first protective film and the second protective film is 5.0×10⁻⁶/K or less, and
a difference in thermal expansion coefficient between the second protective film and the encapsulant is 5.0×10⁻⁶/K or less.

3. The semiconductor device according to claim 1,
wherein the protective film of the plurality of layers is a protective film of three or more layers including a third protective film provided on the second protective film,
the second protective film is larger in thermal expansion coefficient than the first protective film, and smaller in thermal expansion coefficient than the third protective film, and
the third protective film is larger in thermal expansion coefficient than the second protective film, and smaller in thermal expansion coefficient than the encapsulant.

4. The semiconductor device according to claim 1,
wherein the semiconductor substrate has a planar shape of a rectangle, and
the protective film of the plurality of layers is provided in corner portions included in the rectangle of the semiconductor substrate, in the breakdown voltage retention region and the invalid region.

5. The semiconductor device according to claim 4,
wherein the breakdown voltage retention region includes a field limiting ring portion, and
a width of each of the corner portions is larger than a distance from an edge of the semiconductor substrate to an innermost circumference of the field limiting ring portion.

6. The semiconductor device according to claim 1,
wherein the encapsulant is provided on the second protective film,
an upper surface of the second protective film includes a roughness pattern,
a film thickness of the second protective film in a protrusion of the roughness pattern is 8.0 μm or more, and
a film thickness of the second protective film in a recess of the roughness pattern is 4.0 μm or more.
